(19) United States
(12) Patent Application Publication
(10) Pub. No.: US 2007/0176179 A1
(43) Pub. Date: Aug. 2, 2007

(54) Vertical external cavity surface emitting laser including second harmonic generation crystal having mirror surface

(75) Inventor: Soo-haeng Cho, Suwon-si (KR)

Correspondence Address: BUCHANAN, INGERSOLL & ROONEY PC, POST OFFICE BOX 1404, ALEXANDRIA, VA, 22313-1404, US

(73) Assignee: Samsung Electronics Co., Ltd., Suwon-si (KR)

(21) Appl. No.: 11/490,075

(22) Filed: Jul. 21, 2006

(30) Foreign Application Priority Data
Jan. 10, 2006 (KR) 10-2006-0002690

(51) Int. Cl. H01L 29/04; H01L 29/15; H01L 31/036

(52) U.S. Cl. 257/72

(57) ABSTRACT

Provided is a VECSEL having an SHG crystal with a mirror surface. The VECSEL includes a laser chip, a folding mirror, and the SHG crystal. The laser chip emits rays having a first wavelength, and the folding mirror is disposed a predetermined distance from the laser chip and obliquely disposed with respect to the laser chip to obliquely reflect rays having the first wavelength emitted from the laser chip. The SHG crystal doubles a frequency of rays having the first wavelength reflected by the folding mirror to form rays having a second wavelength. A coating layer is formed on an emitting surface of the SHG crystal to reflect rays having the first wavelength whose frequency has not been doubled and transmit rays having the second wavelength whose frequency has been doubled in one embodiment, whereas in another embodiment it reflects the second wavelength for emission from the back surface of the folding mirror with a different combination of coatings on incident and emitting surfaces.

### CROSS-REFERENCE TO RELATED PATENT APPLICATION

Priority is claimed to Korean Patent Application No. 10-2006-0002690, filed on Jan. 10, 2006, in the Korean Intellectual Property Office, the disclosure of which is incorporated herein in its entirety by reference.

### BACKGROUND OF THE DISCLOSURE

1. Field of the Disclosure

The present disclosure relates to a vertical external cavity surface emitting laser (VECSEL), and more particularly, to a VECSEL including a second harmonic generation (SHG) crystal having a mirror surface.

2. Description of the Related Art

A VECSEL is a laser device providing a high power output exceeding several to several tens of watts by replacing an upper mirror of a vertical cavity surface emitting laser (VCSEL) with an external mirror in order to increase a gain region.

FIG. 1 is a schematic sectional view of a conventional VECSEL 10 having a linear structure. Referring to FIG. 1, the VECSEL 10 includes a laser chip 13 for laser oscillation, an external concave mirror 16 located a predetermined distance from the laser chip 13, and a pump laser 11 obliquely located so that pumping rays are provided to the laser chip 13. Also, a birefringent filter 14 passing only rays of a predetermined wavelength and controlling the polarization direction of an emitting ray, and a second harmonic generation (SHG) crystal 15 doubling the frequency of incident light, may be further located between the laser chip 13 and the external concave mirror 16. For example, the SHG crystal 15 may convert infrared rays emitted from the laser chip 13 into visible rays.

As known in the art, the laser chip 13 has a structure in which a distributed Bragg reflector (DBR) layer and an active layer are sequentially stacked on a substrate. For example, the active layer of the laser chip 13 has a multiple quantum well structure and is excited by pumping rays from the pump laser 11 to emit a ray having a predetermined wavelength. The pump laser 11 allows a ray incident to the laser chip 13 to excite the active layer within the laser chip 13. Here, the wavelength of the pumping rays, emitted from the pump laser 11, should be shorter than that of a ray generated from the laser chip 13. For example, when the laser chip 13 is formed of a Ga semiconductor, the laser chip 13 emits an infrared ray having a wavelength ranging from about 900 nm to 1200 nm. In this case, the pumping rays, emitted from the pump laser 11, may have a wavelength of about 808 nm.

With the above structure, when rays emitted from the pump laser 11 are incident to the laser chip 13 through a lens 12, the active layer of the laser chip 13 is excited to emit an infrared ray. Rays generated in this manner resonate while being repeatedly reflected between the DBR layer of the laser chip 13 and the external concave mirror 16. At this point, rays converted into visible rays by the SHG crystal 15 are output through the external concave mirror 16. For that purpose, the surface of the external mirror 16 is coated to have high reflectance with respect to an infrared ray and have high transmittance with respect to a visible ray. Also, a surface of the SHG crystal 15 is coated to have high reflectance with respect to the visible ray and have high transmittance with respect to the infrared ray so that some of the visible rays reflected by the external mirror 16 may propagate back to the external mirror 16.

The conversion efficiency of the SHG crystal 15 is proportional to the energy density of incident rays. Therefore, a beam diameter of the incident ray may be minimized to increase the conversion efficiency of the SHG crystal 15. For that purpose, the locations of the SHG crystal 15 and the birefringent filter 14 may be exchanged. However, even if the locations of the SHG crystal 15 and the birefringent filter 14 are exchanged, the beam diameter of the incident rays can still only be reduced by a limited amount.

To address this problem, a VECSEL 20 having a folded structure has been proposed as illustrated in FIG. 2. Referring to FIG. 2, the VECSEL 20 includes a laser chip 21, a concave folding mirror 23, a flat mirror 25, a birefringent filter 22 located between the folding mirror 23 and the laser chip 21, and an SHG crystal 24 located between the folding mirror 23 and the flat mirror 25. With this structure, rays emitted from the laser chip 21 are reflected by the folding mirror 23 and then converge near the flat mirror 25. Since the SHG crystal 24 is located near the flat mirror 25, a beam diameter of rays incident to the SHC crystal 24 may be minimized. Here, a surface 23a of the folding mirror 23 has high reflectance with respect to infrared rays. Also, a surface 25a of the flat mirror 25 has high reflectance with respect to infrared rays and has high transmittance with respect to visible rays. Also, one surface 24a of the SHG crystal 24 has high reflectance with respect to visible rays and has high transmittance with respect to infrared rays. Therefore, visible rays converted by the SHG crystal 24 are outputted, and infrared rays resonate in a cavity. However, since the VECSEL 20 illustrated in FIG. 2 includes a lot of mirrors, manufacturing costs increase, parts are difficult to accurately align and the amount of light loss also increases.

FIG. 3 illustrates a VECSEL 30 having the reduced number of mirrors disclosed in U.S. Pat. No. 6,393,038. Referring to FIG. 3, the VECSEL 30 which has a linear structure includes a laser chip having a substrate 32, a DBR layer 33, and an active layer 34, located on a heat sink 31, and an SHG crystal 36 located a predetermined distance from the laser chip. An anti-reflection coating 35 is provided on a lower surface of the SHG crystal 36 facing the laser chip, and a mirror 37 is formed on an upper surface of the SHC crystal 36. Here, the upper surface of the SHG crystal 36 is a convex curved surface, so that the mirror 37 formed on the upper surface of the SHG crystal 36 becomes a concave curved mirror. However, although the VECSEL 30 illustrated in FIG. 3 has the reduced number of mirrors, it still has the problems of the VECSEL 10 of FIG. 1. That is, since the focus of the concave mirror 37 is adjusted at the laser chip to satisfy a resonant condition, it is difficult to reduce the beam diameter of a ray within the SHG crystal 36. Therefore, the efficiency of the SHG crystal 36 decreases. Furthermore, the upper surface of the SHG crystal 36 needs to be processed very precisely in order to form the concave mirror 37 accurately, thus increasing manufacturing costs and time.

### SUMMARY OF THE DISCLOSURE

The present disclosure provides a VECSEL having a simple structure and an SHC crystal having an excellent wavelength conversion efficiency.

The present disclosure also provides a VECSEL in which parts can be easily aligned, and thus reducing manufacturing costs and time.

According to an aspect of the present disclosure, there is provided a VECSEL including: a laser chip emitting rays having a first wavelength; a folding mirror disposed a predetermined distance from the laser chip and disposed obliquely with respect to the laser chip to obliquely reflect the rays having the first wavelength emitted from the laser chip; and an SHG (second harmonic generation) crystal doubling a frequency of the rays having the first wavelength reflected by the folding mirror to form rays having a second wavelength, wherein a coating layer is formed on an emitting surface of the SHG crystal to reflect rays having the first wavelength whose frequency has not been doubled back to the folding mirror, and transmit the rays having the second wavelength whose frequency has been doubled.

A coating layer may be formed on an incident surface of the SHG crystal to transmit the rays having the first wavelength whose frequency has not been doubled and reflect the rays having the second wavelength ray whose frequency has been doubled to the emitting surface of the SHG crystal via the folding mirror.

The rays having the first wavelength emitted from the laser chip resonate between the emitting surface of the SHG crystal and the laser chip.

The rays having the second wavelength whose frequency has been doubled may be outputted through the emitting surface of the SHG crystal.

The VECSEL may further include a birefringent filter, located between the laser chip and the folding mirror, to transmit only rays of predetermined wavelength and control the polarization direction of the transmitted ray.

A mirror surface of the folding mirror may be concave, and the emitting surface of the SHG crystal may be flat.

A focus of the concave folding mirror may be located inside the SHG crystal.

According to another aspect of the present disclosure, there is provided a VECSEL including: a laser chip emitting rays having a first wavelength; a folding mirror spaced from the laser chip and disposed obliquely with respect to the laser chip to obliquely reflect rays having the first wavelength emitted from the laser chip; and an SHG crystal doubling the frequency of the first wavelength ray reflected by the folding mirror to form rays having a second wavelength, wherein a coating layer is formed on an emitting surface of the SHG crystal to reflect both rays having the first wavelength whose frequency has not been doubled and rays having the second wavelength whose frequency has been doubled.

A coating layer serving as an anti-reflection coating layer may be formed on an incident surface of the SHG crystal to prevent reflection of both rays having the first wavelength whose frequency has not been doubled and rays having the second wavelength whose frequency has been doubled.

A coating layer may be formed on the mirror surface of the folding mirror to reflect rays having the first wavelength whose frequency has not been doubled and transmit rays having the second wavelength whose frequency has been doubled, and the second wavelength ray may pass through the folding mirror and be outputted.

### BRIEF DESCRIPTION OF THE DRAWINGS

The above and other features and advantages of the present disclosure will become more apparent by describing in detail exemplary embodiments thereof with reference to the attached drawings in which:

FIG. 1 is a schematic sectional view of a conventional VECSEL having a linear structure;

FIG. 2 is a schematic sectional view of a conventional VECSEL having a folding structure;

FIG. 3 is a schematic sectional view of a conventional VECSEL having another linear structure;

FIG. 4 is a schematic sectional view of a VECSEL having a folding structure according to an embodiment of the present disclosure; and

FIG. 5 is a schematic sectional view of a VECSEL having a folding structure according to another embodiment of the present disclosure.

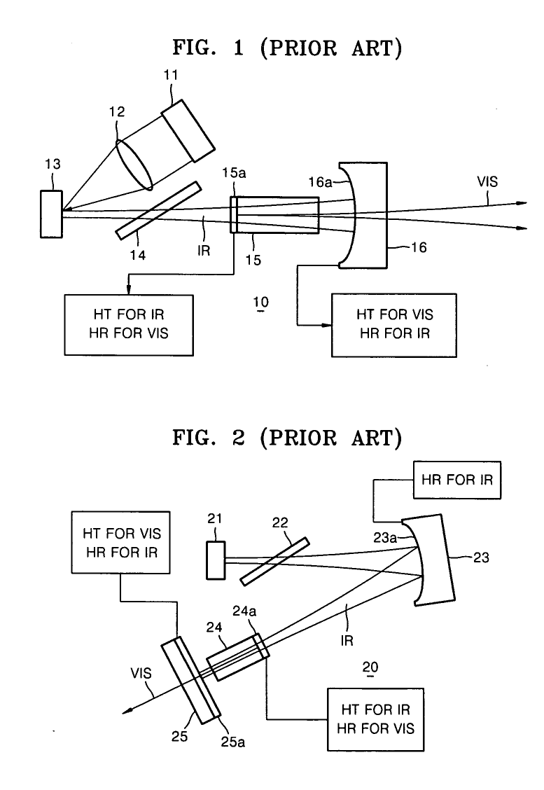

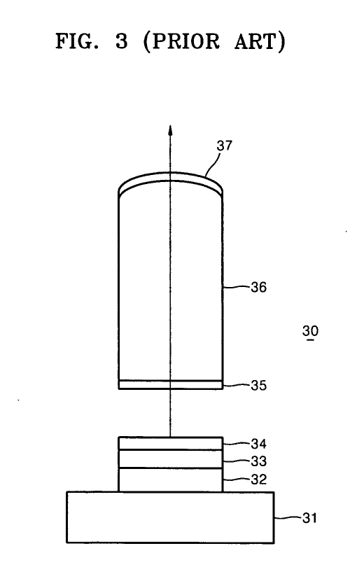

### DETAILED DESCRIPTION OF THE DISCLOSURE

Hereinafter the present disclosure will be described in detail by explaining embodiments of the disclosure with reference to the attached drawings.

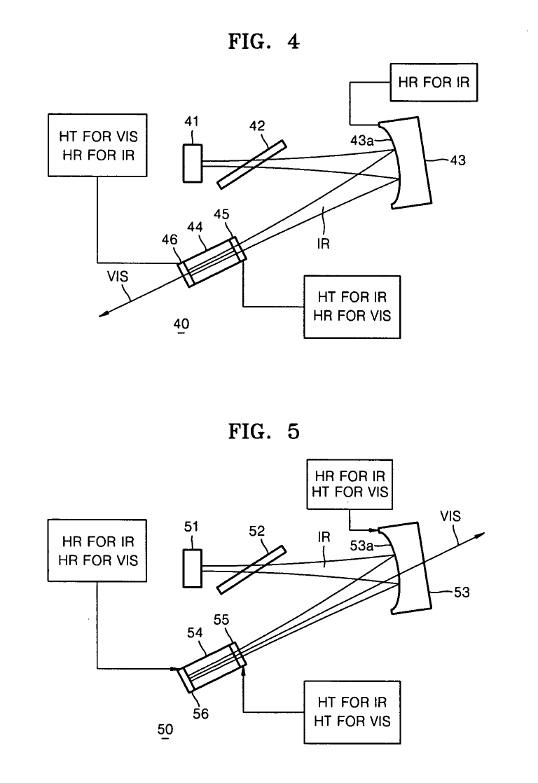

FIG. 4 is a schematic sectional view of a VECSEL 40 having a folding structure according to an embodiment of the present disclosure. Referring to FIG. 4, the VECSEL 40 includes a laser chip 41 emitting rays of a predetermined wavelength, a folding mirror 43 obliquely reflecting the rays emitted from the laser chip 41, and an SHG crystal 44 doubling a frequency of the rays reflected by the folding mirror 43.

The laser chip 41 has a structure formed by sequentially stacking a DBR layer and an active layer on a substrate. The active layer has, for example, a multiple quantum well structure and is excited by pumping rays emitted from a pump laser (not shown) to emit rays of a predetermined wavelength. For example, when the active layer is formed of a Ga semiconductor, the active layer emits infrared rays having a wavelength ranging from about 900 nm to 1200 nm.

The folding mirror 43 is spaced a predetermined distance from the laser chip 41 and is obliquely disposed with respect to the laser chip 41. Referring to FIG. 4, a mirror surface 43a of the folding mirror 43 may have a concave surface to condense light. Also, the mirror surface 43a of the folding mirror 43 is coated to have high reflectance with respect to rays emitted from the laser chip 41. For example, when the laser chip 41 emits infrared rays, the mirror surface 43a of the folding mirror 43 is coated to have high reflectance with respect to infrared rays.

As described above, the SHG crystal 44 doubles the frequency of the rays reflected by the folding mirror 43. The SHG crystal 44 may convert infrared rays that has been emitted from the laser chip 41, into visible rays. The SHG crystal may be a crystal such as periodically poled potassium titanyl phosphate (PPKTP), LiNbO₃, periodically poled LiNbO₃ (PPLN), periodically poled stoichiometric lithium tantalate (PPSLT), KNbO₃, and potassium tantalate niobat (KTN). Referring to FIG. 4, the SHG crystal 44 is located at a position where the rays reflected by the folding mirror 43 are condensed. That is, the focus of the folding mirror 43 may be located inside the SHG crystal 44. Since the wavelength conversion efficiency of the SHG crystal 44 is proportional to the energy density of incident rays as described previously, it is possible to achieve an optimized efficiency by condensing rays in the inside of the SHG crystal 44 using the folding mirror 43.

A coating layer is formed on an emitting surface 46 of the SHG crystal 44 to have high transmittance with respect to visible rays so that the visible rays, whose frequency has been doubled by the SHG crystal 44, may be outputted. Also, the coating layer formed on the emitting surface 46 of the SHG crystal 44 may have high reflectance with respect to infrared rays so that the infrared rays emitted from the laser chip 41 may resonate. Therefore, the VECSEL 40 illustrated in FIG. 4 excludes the flat external mirror 25 of the conventional VECSEL 20 illustrated in FIG. 2, and instead, includes the coating layer formed on the emitting surface 46 of the SHG crystal 44. Also, a coating layer is formed on an incident surface 45 of the SHG crystal 44 to have high reflectance with respect to visible rays so that the visible ray reflected by the emitting surface 46 of the SHG crystal 44, may be reflected back to the emitting surface 46. The coating layer formed on the incident surface 45 of the SHG crystal 44 may have high transmittance with respect to the infrared rays so that the infrared rays emitted from the laser chip 41 may resonate.

Furthermore, a birefringent filter 42 may be located between the laser chip 41 and the folding mirror 43. The wavelength conversion efficiency of the SHG crystal 44 is influenced not only by the energy density of incident rays but also by the wavelength and the polarization direction of incident rays. Generally, rays emitted from the laser chip 41 and resonating within a cavity constitutes a spectrum having a plurality of non-continuous wavelengths. The birefringent filter 42 transmits only rays of a predetermined wavelength and controls the polarization direction of the transmitted rays. Therefore, it is possible to further increase the efficiency of the SHG crystal 44 and enhance the quality of laser rays.

In operation, when pumping rays are provided from the pump laser to the laser chip 41, the active layer of the laser chip 41 is excited to emit, for example, infrared rays. After passing through the birefringent filter 42, the infrared rays are obliquely reflected and condensed inside the SHG crystal 44 by the folding mirror 43. Then, some of the infrared rays are converted into visible rays by the SHG crystal 44 and outputted through the emitting surface 46 of the SHG crystal 44. Some of the visible rays may be reflected by the emitting surface 46, but are reflected again by the incident surface 45 of the SHG crystal 44, and eventually outputted through the emitting surface 46. On the other hand, the infrared rays whose frequency has not been doubled by the SHG crystal 44, are reflected by the emitting surface 46 of the SHG crystal 44. At this point, some of the infrared rays are converted into visible rays and reflected by the incident surface 45 of the SHG crystal 44 and outputted through the emitting surface 46. The infrared rays not converted by the SHG crystal 44 pass through the incident surface 45 of the SHG crystal 44 and are then reflected by the folding mirror 43 and incident to the laser chip 41. These infrared rays are reflected by the DBR layer of the laser chip 41 and the above-described process is repeated. Therefore, the rays emitted from the laser chip 41 are reflected by the folding mirror 43 and resonate between the emitting surface 46 of the SHG crystal 44 and the laser chip 41.

According to an embodiment of the present disclosure, since it is possible to minimize a beam diameter of rays incident to the SHG crystal 44, the SHG crystal 44 may have an optimized efficiency. Also, it is possible to reduce the number of mirrors by forming a coating layer on the emitting surface 46 of the SHG crystal 44 instead of using a separate flat mirror. Therefore, it is possible to shorten a time consumed in accurately aligning parts during a manufacturing process of a laser and to reduce manufacturing costs. Also, the reduction of the number of optical surfaces reduces optical losses caused by the optical surfaces.

FIG. 5 is a schematic sectional view of a VECSEL 50 having a folding structure according to another embodiment of the present disclosure. The type and arrangement of elements adopted in VECSEL 50 illustrated in FIG. 5 are the same as those adopted in the VECSEL 40 illustrated in FIG. 4. Only characteristics of a coating layer and an output position of the lasers ray are different. That is, the VECSEL 50 illustrated in FIG. 5 includes a laser chip 51 emitting rays of a predetermined wavelength ray, a folding mirror 53 spaced a predetermined distance from the laser chip 51 and obliquely disposed with respect to the laser chip 51 to obliquely reflect the rays emitted from the laser chip 51, an SHG crystal 54 doubling a frequency of the rays reflected by the folding mirror 53, and a birefringent filter 52 located between the laser chip 51 and the folding mirror 52 to transmit rays of a predetermined wavelength. As in the VECSEL 40 illustrated in FIG. 4, the folding mirror 53 has a concave surface and the focus of the folding mirror 53 is located inside the SHG crystal 54.

Unlike the VECSEL 40 illustrated in FIG. 4, the VECSEL 50 illustrated in FIG. 5 includes a coating layer formed on an emitting surface 56 of the SHG crystal 54 to have high reflectance with respect to both the rays whose frequency has been doubled and the rays whose frequency has not been doubled. For example, when the laser chip 51 emits infrared rays, the coating layer formed on the emitting surface 56 of the SHG crystal 54 reflects both the infrared rays and visible rays. Also, a coating layer formed on an incident surface 55 of the SHG crystal 54 has high transmittance with respect to both the infrared rays whose frequency has not been doubled and the visible rays whose frequency has been doubled. On the other hand, the folding mirror 53 includes a coating layer formed on a mirror surface 53a and having high reflectance with respect to the infrared rays whose frequency has not been doubled but having high transmittance with respect to the visible rays whose frequency has been doubled.

Infrared rays that are emitted from the laser chip 51 pass through the birefringent filter 52 and are then obliquely reflected by the folding mirror 53 and condensed inside the SHG crystal 54. After that, some of the infrared rays are converted into the visible rays by the SHG crystal 54. The visible rays converted by the SHG crystal 54 and infrared rays that have not been converted by the SHG crystal 54 are reflected by the emitting surface 56 of the SHG crystal 54, and then pass through the incident surface 55 of the SHG crystal 54 and are incident on the folding mirror 53. Here, the visible rays pass through the folding mirror 53 and are outputted, but the infrared rays are reflected by the folding mirror 53 and are incident to the laser chip 51. Subsequently, the infrared rays are reflected by the DBR layer within the laser chip 51 and the above-described process is repeated.

Therefore, in the VECSEL illustrated in FIG. 4, the rays are outputted through the emitting surface 46 of the SHG crystal 44, but in the VECSEL 50 illustrated in FIG. 5, the rays are outputted through the folding mirror 53. Although it is assumed that the laser chips 41 and 51 emit infrared rays and the SHG crystals 44 and 54 convert the infrared rays into visible rays, this assumption is provided for exemplary purposes only, and should not be construed as limiting the scope of the present disclosure. Therefore, rays of various wavelengths may be emitted depending on the kind of laser chip, and accordingly, the coating layers of the SHG crystals 44 and 54 may be appropriately selected.

As is apparent from the above descriptions, since it is possible to minimize the beam diameter of rays incident to the SHG crystal 44, the SHG crystal 44 may have an optimized efficiency. Also, it is possible to reduce the number of mirrors by forming a coating layer on the emitting surface 46 of the SHG crystal 44 instead of using a separate flat mirror. Therefore, it is possible to reduce the time consumed in accurately aligning parts during a manufacturing process of a VECSEL and to reduce manufacturing costs. Also, the reduction of the number of optical surfaces in the VECSEL reduces optical losses caused by the optical surfaces.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A VECSEL (vertical external cavity surface emitting laser) comprising:
a laser chip emitting rays having a first wavelength;
a folding mirror disposed a predetermined distance from the laser chip and disposed obliquely with respect to the laser chip to obliquely reflect the rays having the first wavelength emitted from the laser chip; and
a second harmonic generation (SHG) crystal doubling a frequency of rays having the first wavelength reflected by the folding mirror to form rays having a second wavelength,
wherein a coating layer is formed on an emitting surface of the SHG crystal to reflect rays having the first wavelength, whose frequency has not been doubled, back to the folding mirror, and transmit rays having the second wavelength whose frequency has been doubled.

2. The VECSEL of claim 1, wherein a coating layer is formed on an incident surface of the SHG crystal to transmit rays having the first wavelength whose frequency has not been doubled, and reflect rays having the second wavelength whose frequency has been doubled to an emitting surface of the SHG crystal.

3. The VECSEL of claim 2, wherein the rays having the first wavelength emitted from the laser chip are reflected by the folding mirror, and resonates between the emitting surface of the SHG crystal and the laser chip.

4. The VECSEL of claim 2, wherein the rays having the second wavelength whose frequency has been doubled are outputted through the emitting surface of the SHG crystal.

5. The VECSEL of claim 2, further comprising a birefringent filter located between the laser chip and the folding mirror to transmit only rays of a predetermined wavelength and control a polarization direction of the transmitted rays.

6. The VECSEL of claim 2, wherein a surface of the folding mirror is concave, and the emitting surface of the SHG crystal is flat.

7. The VECSEL of claim 6, wherein a focus of the concave folding mirror is located inside the SHG crystal.

8. A VECSEL comprising:
a laser chip emitting rays of a first wavelength;
a folding mirror disposed a predetermined distance from the laser chip and disposed obliquely with respect to the laser chip to obliquely reflect the rays having the first wavelength emitted from the laser chip; and
an SHG crystal doubling a frequency of the rays having the first wavelength reflected by the folding mirror to form rays of a second wavelength,
wherein a coating layer is formed on an emitting surface of the SHG crystal to reflect both the rays having the first wavelength whose frequency has not been doubled and the rays having the second wavelength whose frequency has been doubled.

9. The VECSEL of claim 8, wherein a coating layer serving as an anti-reflection coating layer is formed on an incident surface of the SHG crystal to prevent reflection of both rays having the first wavelength whose frequency has not been doubled and rays having the second wavelength whose frequency has been doubled.

10. The VECSEL of claim 9, wherein a coating layer is formed on a mirror surface of the folding mirror to reflect the rays having the first wavelength whose frequency has not been doubled and transmit the rays having the second wavelength whose frequency has been doubled, and the rays having the second wavelength pass through the folding mirror and are outputted to the outside.

11. The VECSEL of claim 10, wherein the rays having the first wavelength emitted from the laser chip are reflected by the folding mirror, and resonate between the emitting surface of the SHG crystal and the laser chip.

12. The VECSEL of claim 10, further comprising a birefringent filter located between the laser chip and the folding mirror to transmit only rays of a predetermined wavelength and control a polarization direction of the transmitted rays.

13. The VECSEL of claim 10, wherein the mirror surface of the folding mirror is concave, and the emitting surface of the SHG crystal is flat.

14. The VECSEL of claim 13, wherein the focus of the concave folding mirror is located inside the SHG crystal.
